(19) United States
(12) Patent Application Publication
(10) Pub. No.: US 2005/0125179 A1
(43) Pub. Date: Jun. 9, 2005

(54) LCD overdrive auto-calibration apparatus and method

(75) Inventors: Steve Selby, Scarborough (CA); Andrew MacKinnon, North York (CA)

Correspondence Address: BEYER WEAVER & THOMAS LLP, P.O. BOX 70250, OAKLAND, CA, 94612-0250, US

(73) Assignee: Genesis Microchip Inc., Alviso, CA (US)

(21) Appl. No.: 10/995,845

(22) Filed: Nov. 22, 2004

Related U.S. Application Data
(60) Provisional application No. 60/527,423, filed on Dec. 5, 2003.
(60) Provisional application No. 60/527,543, filed on Dec. 5, 2003.
(60) Provisional application No. 60/527,437, filed on Dec. 5, 2003.

(51) Int. Cl. G01D 18/00; G01P 21/00; G01R 35/00

(52) U.S. Cl. 702/85

(57) ABSTRACT

A method of auto-calibration of a liquid crystal display (LCD) is described. The method is carried out by generating and displaying on the LCD a test patch at a first grey level, generating a first signal based upon the test pattern at the first grey level, generating and displaying a second test patch at a second grey level, generating a second signal based upon the test pattern at the second grey level, and calculating an entry to an LCD overdrive table based upon the first and the second signal.

### REFERENCE TO RELATED APPLICATIONS

This patent application takes priority under 35 U.S.C. 119(e) to (i) U.S. Provisional Patent Application No.: 60/527,423, filed on Dec. 5, 2003 (Attorney Docket No. GENSP0114P) entitled “LCD OVERDRIVE AUTOCALIBRATION” by Selby, (ii) U.S. Provisional Patent Application No.: 60/527,543, filed on Dec. 5, 2003 (Attorney Docket No. GENSP0115P) entitled “METHOD OF IMPROVING FIXED PIXEL DISPLAY RESPONSE TIME by Selby, and (iii) U.S. Provisional Patent Application No.: 60/527,437, filed on Dec. 5, 2003 (Attorney Docket No. GENSP0116P) entitled “METHOD AND APPARATUS FOR ENHANCING THE APPEARANCE OF MOTION ON AN LCD PANEL” by Selby.

### BACKGROUND

I. Field of the Invention

The invention relates to display devices. More specifically, the invention describes a method and apparatus for enhancing the appearance of motion on an LCD panel display.

II. Overview

Each pixel of an LCD panel can be directed to assume a luminance value discretized to the standard set [0, 1, 2, . . . , 255] where a triplet of such pixels provides the R, G, and B components that make up an arbitrary color which is updated each frame time, typically 1/60^{th} of a second. The problem with LCD pixels is that they respond sluggishly to an input command in that the pixels arrive at their target values only after several frames have elapsed, and the resulting display artifacts—“ghost” images of rapidly moving objects—are disconcerting. Ghosting occurs when the response speed of the LCD is not fast enough to keep up with the frame rate. In this case, the transition from one pixel value to another cannot be attained within the desired time frame since LCDs rely on the ability of the liquid crystal to orient itself under the influence of an electric field. Therefore, since the liquid crystal must physically move in order to change intensity, the viscous nature of the liquid crystal material itself contributes to the appearance of ghosting artifacts.

In order to reduce and/or eliminate this deterioration in image quality, the LC response time is reduced by overdriving the pixel values such that a target pixel value is reached, or almost reached, within a single frame period. In particular, by biasing the input voltage of a given pixel to an overdriven pixel value that exceeds the target pixel value for the current frame, the transition between the starting pixel value and target pixel value is accelerated in such a way that the pixel is driven to the target pixel value within the designated frame period. However, in order to efficiently calculate the overdrive pixel value, an LCD overdrive table is used that provides the appropriate overdrive pixel value that corresponds to a start, target pixel pair.

Accordingly, in an LCD controller, a LCD overdrive look up table (or LUT) is used to remap 8-bit values to the LCD panel in a current frame in order to speed the transition from the start pixel value to the target pixel value. Since each panel has different physical characteristics governing its liquid crystal element response time, each panel must be characterized to determine the proper transfer function to be used in the lookup table. In the absence of software that automatically performs the calibration, it must be performed manually. Since the calibration requires over 80 separate measurements, manual calibration is time-consuming and fraught with potential for human error.

Therefore, what is required is a method, system, and apparatus that automatically calibrates LCD panels and calculates the resultant calibration data used in populating an LCD overdrive table.

### SUMMARY OF THE DISCLOSURE

What is provided is a method, apparatus, and system suitable for auto-calibrating a liquid crystal display (LCD) panel. In one embodiment, the method is carried out by generating and displaying on the LCD a test patch at a first grey level, generating a first signal based upon the test pattern at the first grey level, generating and displaying a second test patch at a second grey level, generating a second signal based upon the test pattern at the second grey level, and calculating an entry to an LCD overdrive table based upon the first and the second signal.

In another embodiment, an auto-calibration system suitable for automatically calibrating a liquid crystal display (LCD) is described. The system includes a processor unit and an onscreen display generator unit coupled to the LCD and the processor unit arranged to generate and display on the LCD a first test patch at a first grey level at a first time slot and generate and display on the LCD a second test patch at a second grey level at a second time slot under control of the processor unit. The system also includes a photosensitive detector coupled to the processor unit arranged to generate a first signal and a second signal each based upon light received from the first patch and the second patch, respectively. The processor in turn calculates an entry to an LCD overdrive table based upon the first and the second signal.

Computer program product for auto-calibration of a liquid crystal display (LCD). The computer program product includes computer code for generating and displaying on the LCD a test patch at a first grey level, computer code for generating a first signal based upon the test pattern at the first grey level, computer code for generating and displaying a second test patch at a second grey level, computer code for generating a second signal based upon the test pattern at the second grey level, computer code for calculating an entry to an LCD overdrive table based upon the first and the second signal, and computer readable medium for storing the computer code.

In yet another embodiment, a method of automatically calibrating a liquid crystal display (LCD) is disclosed. The method is performed by displaying a test pattern on the LCD and automatically populating an overdrive table based upon the displayed test pattern.

### BRIEF DESCRIPTION OF THE DRAWINGS

FIG. 1 shows an exemplary overdrive table.

FIG. 2 shows a system suitable for implementing an LCD auto-calibration process in accordance with an embodiment of the invention.

FIG. 3 shows a flowchart detailing a process for auto-calibrating an LCD panel in accordance with an embodiment of the invention.

FIG. 4 shows a particular implementation of the display test pattern step of the process described with respect to FIG. 3 above as a process.

FIG. 5 that shows a particular implementation of the step 410

FIG. 6 illustrates an exemplary system employed to implement the invention.

### DETAILED DESCRIPTION OF SELECTED EMBODIMENTS

Reference will now be made in detail to a particular embodiment of the invention an example of which is illustrated in the accompanying drawings. While the invention will be described in conjunction with the particular embodiment, it will be understood that it is not intended to limit the invention to the described embodiment. To the contrary, it is intended to cover alternatives, modifications, and equivalents as may be included within the spirit and scope of the invention as defined by the appended claims.

It should be noted that even though the invention is described with respect to a specific embodiment having a pixel bit size (or depth) of 8 bits (representative of 256 levels), the invention is also applicable to embodiments having pixels of other bit depths, such as 10-bit pixels.

One of the keys to the overdrive method is accurate characterization of the LCD panel's optical response. An accurate model allows the overdrive to more accurately predict the response to a given pixel thereby allowing a more accurate selection of overdriven value and predicted pixel values. The liquid crystals must physically rotate and thus its viscosity determines how quickly this rotation can take place. It is the speed of this rotation that determines the response time of a given LCD panel.

In order to improve the performance of slow LCD panels, the performance of the LCD panel is first characterized by, for example, taking a series of measurements that show what each pixel will do by the end of one frame time. Such measurements are taken for a representative pixel (or pixels) each being initially at a starting pixel value s that is then commanded toward a target value t (where s and t each take on integer values from 0 to 255). If the pixel value actually attained in one frame time is p, then
p=fₛ(t) (1)

where fₛ is the one-frame pixel-response function corresponding to a fixed start-pixel s. For example, the one-frame pixel response function fₛ (t) for a pixel having a start pixel value s=32 and a target pixel value t=192 that can only reach a pixel value p=100 is represented as f₃₂(192)=100.

For slow panels (where most if not all targets can not be reached within a frame time) functions m(s) and M(s) give the minimum pixel value and maximum pixel value, respectively, reachable in one frame time as functions of s that define maximum-effort curves. In order to reach a pixel value p that lies within the interval [m(s), M(s)], equation (1) is solved for the argument that produces pixel value p referred to as the overdrive pixel value that will achieve the goal (i.e., pixel value p) in one frame time. If p<m(s), then the overdrive pixel value is taken as having a best-effort value of 0, with m(s) being the best-effort result achieved. Likewise, if p>M(s) then the overdrive pixel is taken to be 255, with M(s) being the best-effort result. Thus, for a given start pixel s, overdrive function gₛ can be defined by equation 2 as

$${g}_{s} ( p ) = \{ \begin{matrix}0 , & p < m ( s ) \\ {f}_{s}^{- 1} ( p ) , & m ( s ) \leq p \leq M ( s ) \\ 255 , & p > M ( s )\end{matrix} \qquad ( 2 )$$

In this way, the overdrive pixel value is effective in compelling the pixel to reach its target value in the non-saturation region and M(s) and m(s) in the saturation regions S_{M} and Sₘ, respectively.

Using any of a number of non-inertial approaches (i.e., one that ignores pixel velocity) it is possible to create an overdrive table that shows, for each starting pixel and each target pixel, the command pixel that will most-likely cause the target pixel value to be achieved at the end of one frame time. In an ideal case, the overdrive table is formed of a lookup table with 256 columns—one for each starting pixel in the range 0 to 255—and likewise 256 rows, one for each possible target. However, it isn't practical to store a table of that size (256×256) so by sub-sampling the pixel array at every 32^{nd} pixel, for example, using a reference sequence:
pix={0, 32, 64, 96, 128, 160, 192, 224, 255} (3)

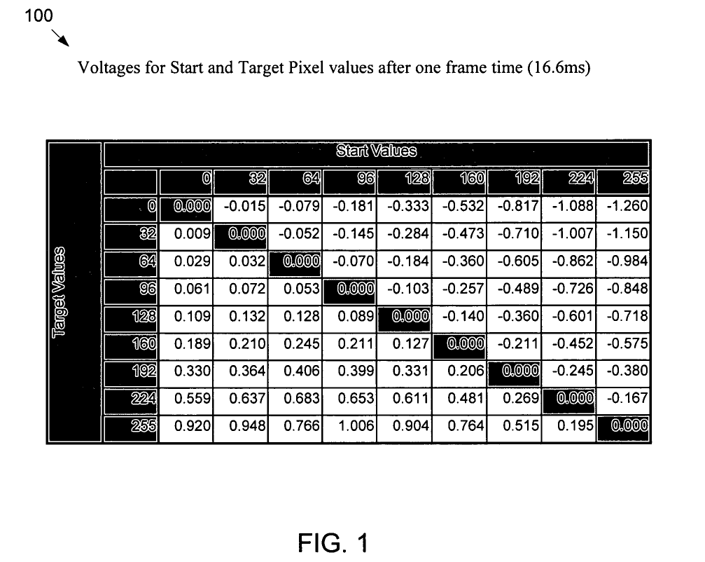

(in which the last entry is truncated to 255), a smaller 9×9 is developed that greatly reduces the amount of memory and computational resources required at runtime. One such overdrive table 100 configured in such a way that a start pixel is given by column j and a target pixel by row i is shown in FIG. 1.

In order to take advantage of the overdrive table, an LCD panel's response time must be determined for at least each of the start and target pixel values enumerated in the overdrive LUT. Therefore, an auto-calibration procedure in accordance with the invention is hereinafter described suitable for use with any number and kind of LCD panels.

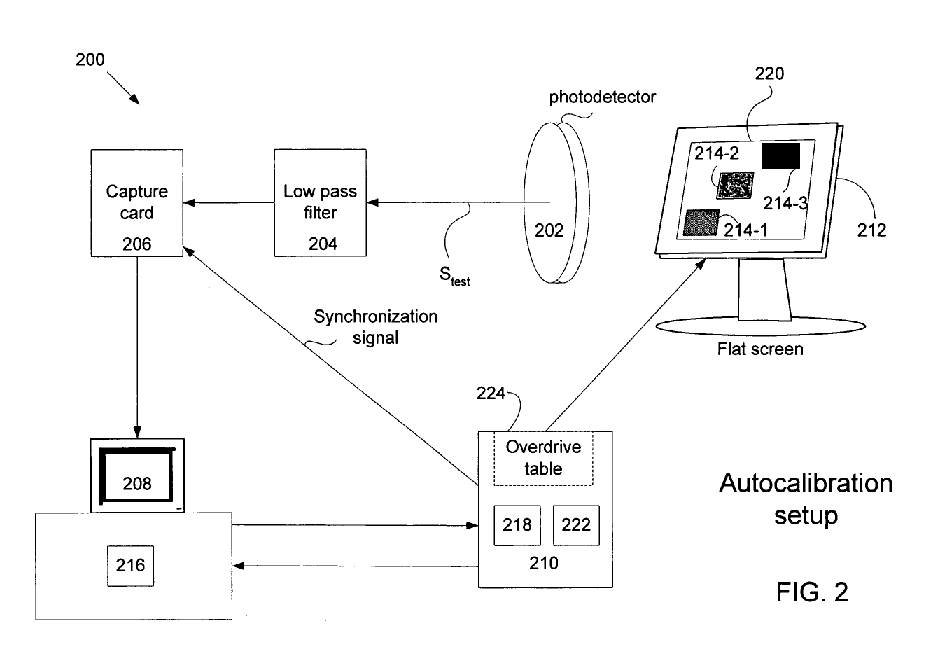

Accordingly, FIG. 2 shows a system 200 suitable for implementing an LCD auto-calibration process in accordance with an embodiment of the invention. The system 200 includes a photosensor 202 coupled to a filter 204 that in turn provides filtered data to a capture card 206 that provides data to a computer 208. (It should be noted that the photosensor 202 can be any of a number of commercially available photosensors such as the PDA55 or the PDA500 manufactured by Thorlabs, Inc. of Newton, N.J.). The computer 208, in turn, provides data to an LCD controller unit 210 that is used to drive an LCD 212 being calibrated. During calibration, the LCD panel 212 displays a test pattern 214 during a test sequence as determined by auto-calibration software 216 resident on the computer 208 and mediated by the LCD controller unit 210. It should be noted that in one specific embodiment of the invention an (optical) synchronization signal is used for additional synchronization above and beyond the physical (electrical) sync signal. However, this optical sync is not strictly necessary and may be omitted in an alternate implementation

In the described embodiment, the test pattern takes the form of a number of patches 214 each of an arbitrary grey level (it should be noted that although the test pattern is shown schematically as 214-1 through 214-3, in the described embodiment, the various patches 214 are displayed one at a time on the LCD 212). Therefore, for proper LCD calibration, the system 200 must be able to display each patch 214 (at an arbitrary grey level) per output frame, with no frame tear, frame drops, repeated frames, or other visible glitches. In addition, there should be a known latency (in frames) between the issuance of a patch display command and its actual display on the LCD 212 thereby synchronizing the display and corresponding signal capture by the photosensor 202.

Since the starting point of transitions between grey levels of only slightly different values can be difficult to distinguish, the frame in which the transition starts must be known for accurate measurement. In addition, the grey patch must be able to be displayed at an arbitrary size and position on the LCD 212. Since the LCD 212 is addressed row by row, there is a small temporal lag in the transition from one grey level to the next in pixels of different lines giving rise to a slight temporal “smearing” of the transition waveform. This smearing is mitigated by reducing the vertical size of the patch, however, the patch must still be large enough to provide sufficient light for the photosensor 202 to provide accurate measurement. In the described embodiment, these competing requirements, (patch size to reduce smearing vs. providing sufficient light output) is done dynamically, since different LCDs have different light levels over a given area. Also, the position must be dynamically changeable to ensure the best correlation between sensor and patch position on the screen.

In the described embodiment, an on-chip On Screen Display (OSD) generator 218 generates an OSD 220 formed of several “tiles” virtually stored in a memory 222 (such as SRAM 222) that mediates between the size of the patch to optimize image smearing and light output. Accordingly, each tile is formed of a data structure that includes such information as tile position and size, highlight position and size, transparency/blend/blink information, and a pointer to the tile data in SRAM. The tile data is a set of 1, 2, or 4 bit per pixel data, each of which is expanded into an index to a 256 entry color lookup table (CLUT). In the described embodiment, the CLUT is a 256 word structure containing 256 24-bit colors that allows for up to 256 24-bit colors to be displayed in a particular OSD 220. In the currently described implementation, there are two lookup tables, one active and one pending. The active CLUT is used for the displayed OSD while the pending CLUT can then be written to without causing glitches on the LCD 212. Once the pending CLUT has finished being updated, it can be switched with the active CLUT.

Since the auto-calibration procedure requires only that a single patch consisting of one grey value be displayed on the screen at a time, no tile is stored in SDRAM. The color index in command SRAM indexes into the CLUT and fills the entire OSD with that color. Therefore, by filling up the CLUT with 256 gray levels, any gray level can be displayed simply by changing the color index in the command SRAM. In addition, the position and the size of the OSD 220 can be changed by corresponding parameters in command SRAM

It should be noted that while a particular test sequence is running, the photosensor 202 (placed in such a position to gather light from the LCD panel 212) converts the LCD light output generated by the test patches 202 to a test signal Sₜₑₛₜ. The signal Sₜₑₛₜ is representative of the pixel transitions of the various test patterns it is primarily composed of low frequency components and as such generally has a frequency on the order of just a few times the frame rate. In order to reduce any spurious high frequency noise, the signal Sₜₑₛₜ is filtered by the filter 204 having a cutoff frequency of approximately 1 kHz. The filtered signal is then sampled by the capture card 206 in preparation for input to the auto-calibration software 216 on the computer 208.

Once the appropriate measurements for the particular test sequence has been received and processed, the computer 208 calculates appropriate LCD overdrive table values used to populate an LCD overdrive table 224 used by the LCD controller unit 210 to control the LCD panel 212 during normal operation. It should be noted that each vertical refresh rate creates a different response in the LCD and must be measured and recorded separately.

It should also be noted that since the LCD optical response can vary widely from on-axis to off-axis viewing and has a wide acceptance angle into its photoreceptor can cause measuring inaccuracies due to not only off-axis light from the LCD itself but also from environmental ambient light such as overhead fluorescent or sunlight. Therefore, an external collimator (not shown) may be desirable to eliminate off-axis light, however, the collimator will also reduce the total light sampled and may thus reduce the signal-to-noise ratio of the final sensor output.

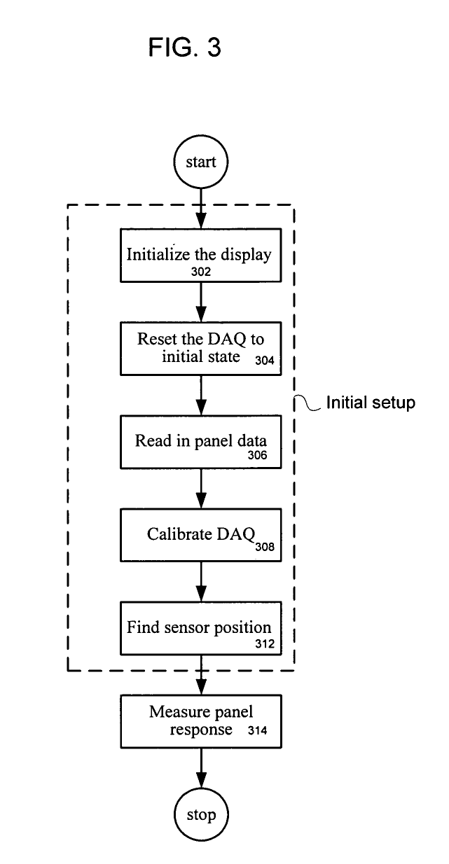

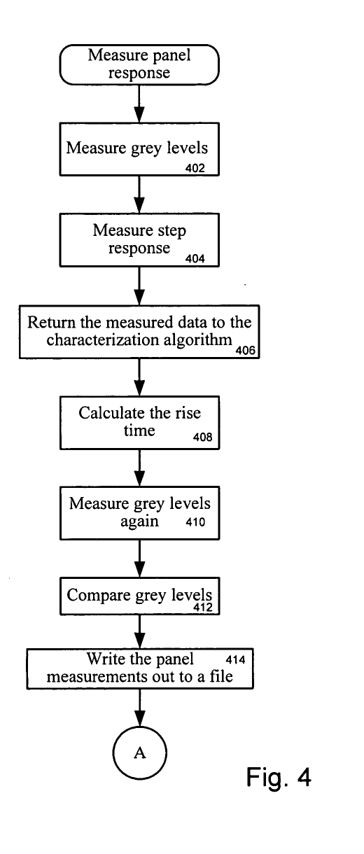

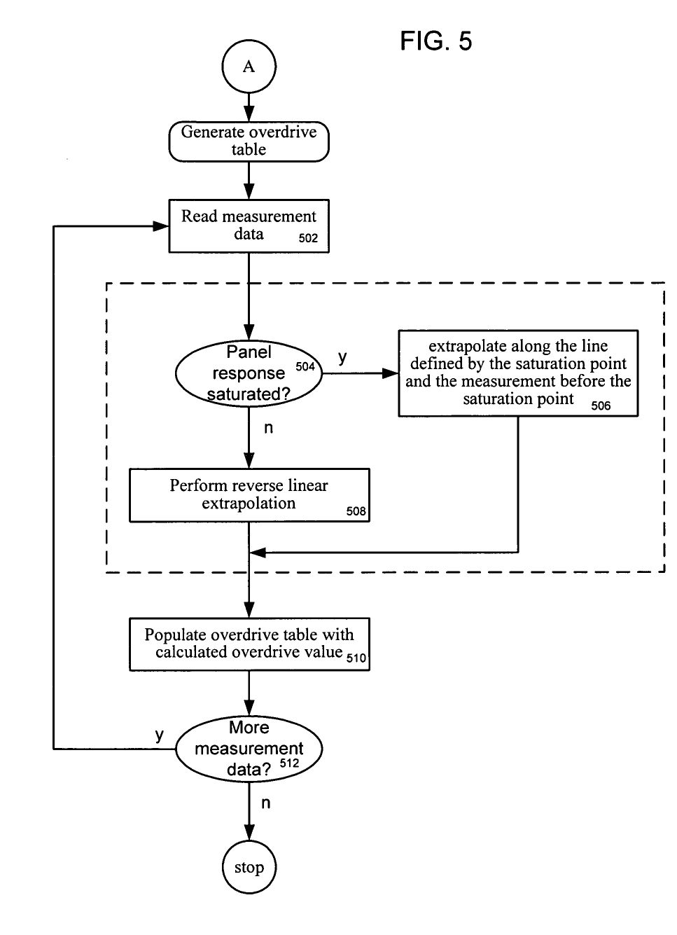

A method for auto-calibrating an LCD panel in accordance with an embodiment of the invention will now be discussed with regards to FIGS. 3 through 5 representing an initial set up process 300 (FIG. 3), a panel response measurement process 400 (FIG. 4) and a generating an LCD overdrive table process 500 (FIG. 5).

Accordingly, the initial set up process 300 by initializing the display by resetting the data acquisition device, or DAQ device, by checking that a supported DAQ device is connected to the PC. In the described embodiment, a data structure that lists the DAQ device properties (gain settings, bit resolution, etc.) is filled out and the DAQ device is reset to an initial state at 302. Next at 304, panel data is read in while at 306, the DAQ device is calibrated by verifying that the minimum necessary (two) input channels exist, that the DAQ device has a sample resolution between 8 and 16 bits, and that the array of gain settings is ordered. In addition, a full screen grey patch with RGB=(255,255,255) is displayed to find the gain setting for the DAQ device that provides the best resolution without over-saturation. In addition, the synchronization signal provided from the board is toggled at the specified rate; the sync polarity is checked to ensure that the sensor voltage is relatively stable.

Next at 308, a sensor position is found. Since each scan line in the LCD is addressed sequentially, the vertical position of the optical sensor will determine the exact instant each step response transition measurement must start. This part of the algorithm displays patches on the screen using an overlapping binary search to find the sensor's vertical position. In the described embodiment, patches with a vertical height of one half that of the LCD screen is displayed. Three such patches are measured, covering the top, bottom, and middle of the LCD panel. The patch with the strongest optical response is then subdivided in the next iteration, each of which uses patches with half the vertical height of those of the previous iteration. The midpoint of the smallest patch with a reasonable response (above a defined threshold) is taken to be the sensor's vertical midpoint. Using this line number, the delay in samples from the vertical synchronization signal to the sensor midpoint is calculated and stored. Once the initial set up is complete, the panel response is measured at 310.

FIG. 4 shows a process 400 that describes a particular implementation of the panel response measurement operation 310 described above. At 402, grey levels are measured by displaying and measuring multiple grey patch values to generate a grey level to sample level correspondence curve (each grey level is sampled multiple times to average out noise effects). Next at 404, a step response is measured by iterating through each combination of steps. For example, a 9×9 coarse table (every 32 grey levels), requires 36 rising and 36 falling steps. Each iteration measures one rising and one falling step. The panel alternates between a lower and higher grey level; each grey level is displayed for a chosen number of frames, and each low to high and high to low transition is repeated for a chosen number of times. The number of frames to display a given grey level is usually set quite high (˜40 frames) to allow the panel to settle to the new grey level. Multiple repetitions of each step are measured to average out noise effects. It should be noted that in the described embodiment, the DAQ device returns the measured data to the characterization algorithm at 408 where each set of data contains both the optical sensor data and the vertical sync data, which are measured simultaneously. The measured data must conform to the following: the sync data must contain the full leading and trailing edge of the first sync pulse, and the first rising edge transition from the optical sensor must occur in the frame immediately following the first sync.

It should be noted that throughout the measurement process, a number of error checks are performed that include checking the polarity of the sync signal at the first sample of each iteration to help ensure the sample stream from the DLL conform to the first condition above and at each transition, the sensor sample at the transition starting point must be close to the corresponding level obtained during the measure grey levels step above. The starting point is the one calculated during the Find sensor position procedure of the algorithm setup above. Each measured transition must rise from start to end if expecting a rising edge transition, or fall if expecting a falling edge transition. Next at 408, rise times of 10-90% and 0-99% are measured by first calculating the corresponding grey level values of the starting and ending percentages based on the static grey level measurements. Then, from the start of the first frame of the sequence, it compares the data to the starting and ending grey levels required in order to calculate the number of samples in between. The number of samples is translated into time in milliseconds to find the rise/fall times. Multiple repetitions of each step are measured to average out noise effects. At 410, the grey levels are measured again and at 412, the grey levels are compared since the grey level measurements must be consistent from the first to the second set of measurements. If they drift excessively, it could indicate insufficient panel warm up time, a sudden change in the ambient light level, or similar effects which could seriously impair the reliability of the measurements. At 414, the panel measurements are sent to a file.

It should be noted that optionally peak-to-peak one-frame step measurements are performed by iterating through each combination of steps (36 rising and 36 falling steps), displaying each grey level one frame at a time and measuring the peak-to-peak voltage difference between the two grey levels. Each step is repeated 30 times to average out noise and instability. This information will be used later to compare to the overdriven peak-to-peak results.

FIG. 5 shows a process 500 for generating an overdrive table based upon the panel measurements provided to the file of the operation 414. At 502, the panel data is read from the file and at 504 a determination is made that for each transition is the panel response saturated. If the panel response is saturated (i.e. the LCD cannot reach the desired grey level even if driven to grey 0 or grey 255), then at 506 the an extrapolation along the line defined by the saturation point and the measurement before the saturation point thereby preserving the linear interpolation in the area between the saturated portion and the valid measurement portion creating a 10-bit signed value, −512 to +511. On the other hand, if the panel response is not saturated, then at 508 the overdrive value is calculated by simple reverse linear interpolation and in any case, at 510, the overdrive value is assigned to the overdrive table. At 512, if more measurement data is available, then control is passed back to 502, otherwise the process ends.

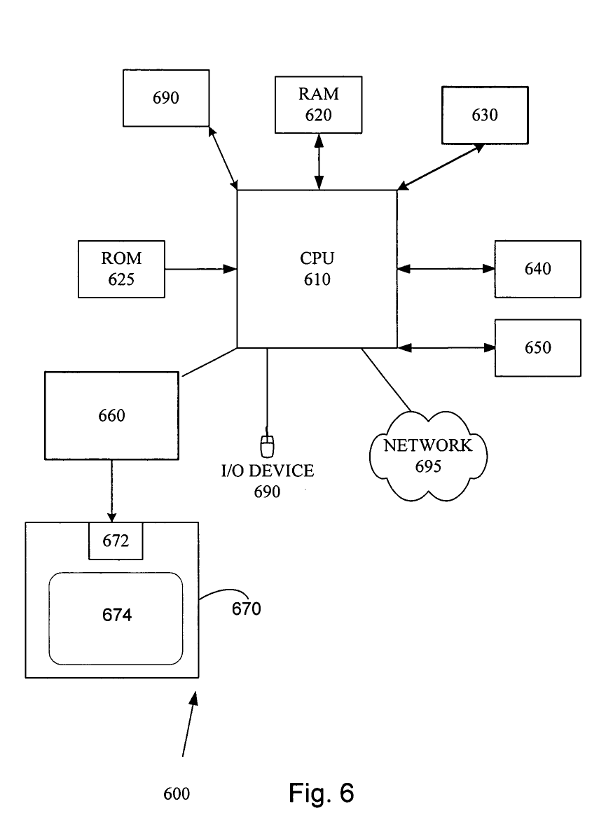

FIG. 6 illustrates a system 600 employed to implement the invention. Computer system 600 is only an example of a graphics system in which the present invention can be implemented. System 600 includes central processing unit (CPU) 610, random access memory (RAM) 620, read only memory (ROM) 625, one or more peripherals 630, graphics controller 660, primary storage devices 640 and 650, and digital display unit 670. CPUs 610 are also coupled to one or more input/output devices 690 that may include, but are not limited to, devices such as, track balls, mice, keyboards, microphones, touch-sensitive displays, transducer card readers, magnetic or paper tape readers, tablets, styluses, voice or handwriting recognizers, or other well-known input devices such as, of course, other computers. Graphics controller 660 generates image data and a corresponding reference signal, and provides both to digital display unit 670. The image data can be generated, for example, based on pixel data received from CPU 610 or from an external encode (not shown). In one embodiment, the image data is provided in RGB format and the reference signal includes the VSyNC and HsyNc signals well known in the art. However, it should be understood that the present invention could be implemented with image, data and/or reference signals in other formats. For example, image data can include video signal data also with a corresponding time reference signal.

Although only a few embodiments of the present invention have been described, it should be understood that the present invention might be embodied in many other specific forms without departing from the spirit or the scope of the present invention. The present examples are to be considered as illustrative and not restrictive, and the invention is not to be limited to the details given herein, but may be modified within the scope of the appended claims along with their full scope of equivalents.

While this invention has been described in terms of a described embodiment, there are alterations, permutations, and equivalents that fall within the scope of this invention. It should also be noted that there are many alternative ways of implementing both the process and apparatus of the present invention. It is therefore intended that the invention be interpreted as including all such alterations, permutations, and equivalents as fall within the true spirit and scope of the present invention.

1. A method of auto-calibrating a pixel overdrive table to a liquid crystal display (LCD), comprising:
generating and displaying on the LCD a test patch at a first grey level;
generating a first signal based upon the test pattern at the first grey level;
generating and displaying a second test patch at a second grey level;
generating a second signal based upon the test pattern at the second grey level; and
calculating an entry to the LCD overdrive table based upon the first and the second signal.

2. The method as recited in claim 1, further comprising:
displaying a black background on the LCD; and
setting a test patch position and size with respect to a pre-selected LCD panel reference point.

3. The method as recited in claim 2, further comprising:
replacing the test patch with a pattern of alternating grey patches; and
preceding each of the grey patches by an optical sync pulse.

4. The method as recited in claim 3, wherein the optical sync pulse comprises:
transitioning from a grey level 0 to a grey level 255;
transistioning from the grey level 255 to the grey level 0; and
displaying each grey level on the LCD panel for a number of frames sufficiently enough to long to allow the LCD panel to settle back to the grey level 0 between the sync pulse and the start of a next transition.

5. An auto-calibration system suitable for automatically calibrating a liquid crystal display (LCD), comprising:
a processor unit;
an onscreen display generator unit coupled to the LCD and the processor unit arranged to generate and display on the LCD a first test patch at a first grey level at a first time slot and generate and display on the LCD a second test patch at a second grey level at a second time slot under control of the processor unit;
a photosensitive detector electrically coupled to the processor unit arranged to generate a first signal and a second signal each based upon light received from the first patch and the second patch, respectively; and
calculating an entry to an LCD overdrive table based upon the first and the second signal.

6. The system as recited in claim 5, wherein the OSD generator displays a black background on the LCD panel and sets a test patch position and size with respect to a pre-selected LCD panel reference point.

7. The system as recited in claim 6, further comprising:
an optical sync pulse generator coupled to the OSD generator wherein the OSD generator replaces the test patch with a pattern of alternating grey patches and precedes each of the grey patches by an optical sync pulse generated by the optical sync pulse generator.

8. The system as recited in claim 7, wherein optical sync pulse generator generates the optical sync pulse by transitioning from a grey level 0 to a grey level 255 and back again and displaying each grey level on the LCD panel for a number of frames sufficiently enough to long to allow the LCD panel to settle back to the grey level 0 between the sync pulse and the start of a next transition.

9. Computer program product for auto-calibration of a liquid crystal display (LCD) panel, comprising:
computer code for generating and displaying on the LCD a test patch at a first grey level;
computer code for generating a first signal based upon the test pattern at the first grey level;
computer code for generating and displaying a second test patch at a second grey level;
computer code for generating a second signal based upon the test pattern at the second grey level;
computer code for calculating an entry to an LCD overdrive table based upon the first and the second signal; and
computer readable medium for storing the computer code.

10. The computer program product as recited in claim 9, further comprising:
computer code for displaying a black background on the LCD; and
computer code for setting a test patch position and size with respect to a pre-selected LCD panel reference point.

11. The computer program product as recited in claim 10, further comprising:
computer code for replacing the test patch with a pattern of alternating grey patches; and
computer code for preceding each of the grey patches by an optical sync pulse.

12. The computer program product as recited in claim 11, wherein the optical sync pulse comprises:
computer code for transitioning from a grey level 0 to a grey level 255;
computer code for transistioning from the grey level 255 to the grey level 0; and
computer code for displaying each grey level on the LCD panel for a number of frames sufficiently enough to long to allow the LCD panel to settle back to the grey level 0 between the sync pulse and the start of a next transition.

13. A method of automatically calibrating a liquid crystal display (LCD), comprising:
displaying a test pattern on the LCD; and
automatically populating an overdrive table based upon the displayed test pattern.
